(19) United States
(12) Patent Application Publication
(10) Pub. No.: US 2026/0190586 A1
(43) Pub. Date: Jul. 2, 2026

(54) DISPLAY DEVICE

(71) Applicant: LG Display Co., Ltd., Seoul (KR)

(72) Inventors: ByungJune MUN, Gumi-si (KR); Hyunjik BAE, Daegu (KR); Jungseop YOON, Chilgok-gun (KR)

(73) Assignee: LG Display Co., Ltd., Seoul (KR)

(21) Appl. No.: 19/232,550

(22) Filed: Jun. 9, 2025

(30) Foreign Application Priority Data
Dec. 30, 2024 (KR) 10-2024-0200850

(51) Int. Cl. H10H 29/855; G06F 3/044; H10H 29/34; H10H 29/853

(52) U.S. Cl. CPC H10H 29/855; G06F 3/0443; H10H 29/345; H10H 29/853

(57) ABSTRACT

A display device in some examples includes a substrate, a plurality of light emitting diodes disposed on the substrate, an encapsulation member disposed on the plurality of light emitting diodes, an interlayer insulating layer which is disposed on the encapsulation member and includes a trench structure on a top surface thereof, a barrier layer which is disposed along the trench structure on the interlayer insulating layer, and a plurality of optical members which cover ends of the barrier layer and are disposed so as to overlap the plurality of light emitting diodes.

### CROSS-REFERENCE TO RELATED APPLICATIONS

This application claims priority to Korean Patent Application No. 10-2024-0200850 filed on Dec. 30, 2024, in the Korean Intellectual Property Office, the disclosure of which is hereby expressly incorporated by reference into the present application.

### BACKGROUND

### Field

The present disclosure relates to a display device, and more particularly, to a display device in which a light leakage phenomenon according to a viewing angle is effectively addressed.

### Discussion of the Related Art

As the technology in modern society develops, display devices are used in various ways to provide information to users. The display devices include not only electronic signs which simply transmit visual information in one direction, but also various electronic devices which need higher level of technology to check a user's input and provide information in response to the checked input.

For example, a display device is included in a vehicle to provide various information to a driver and passengers of the vehicle. However, the display device of the vehicle needs to appropriately display contents without interrupting the operation of the vehicle. For example, the display device needs to limit the display of the contents which can reduce the concentration on the driving while the vehicle is in operation.

### SUMMARY OF THE DISCLOSURE

An object to be achieved by the present disclosure is to provide a display device which suppresses light emitted from a light emitting diode from being leaked to the other optical member disposed therearound.

Another object to be achieved by the present disclosure is to provide a display device which suppresses degradation of a viewing angle cur-off performance.

Still another object to be achieved by the present disclosure is to provide a display device with an improved luminous efficiency.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device comprises a substrate, a plurality of light emitting diodes disposed on the substrate, an encapsulation member disposed on the plurality of light emitting diodes, an interlayer insulating layer which is disposed on the encapsulation member and includes a trench structure on a top surface, a barrier layer which is disposed along the trench structure on the interlayer insulating layer, and a plurality of optical members which cover ends (or edges) of the barrier layer and are disposed so as to overlap the plurality of light emitting diodes.

According to another aspect of the present disclosure, there is provided a display device. The display device comprises a substrate, a bank disposed on the substrate, a first light emitting diode which is disposed on the substrate and includes a first emission area defined by the bank, a second light emitting diode which is disposed on the substrate, includes a second emission area defined by the bank, and emits the same color light as the first light emitting diode, an interlayer insulating layer which covers the first light emitting diode and the second light emitting diode and includes a groove or a hole on a top surface overlapping the bank, a barrier layer which is disposed along the groove or hole on the interlayer insulating layer, a first optical member which covers ends (or edges) of the barrier layer and overlaps the first emission area, and a second optical member which covers ends (or edges) of the barrier layer and overlaps the second emission area.

According to yet another aspect of the present disclosure, there is provided a display device. The display device comprises a substrate; a plurality of light emitting diodes disposed on the substrate; an encapsulation member disposed on the plurality of light emitting diodes; an interlayer insulating layer which is disposed on the encapsulation member and includes a trench structure on a top surface; a barrier layer which is disposed along the trench structure on the interlayer insulating layer; and a plurality of optical members which are disposed on the interlayer insulating layer, overlap the plurality of light emitting diodes, and abut ends of the barrier layer.

According to still another aspect of the present disclosure, there is provided a display device. The display device comprises a substrate; a bank disposed on the substrate; a first light emitting diode which is disposed on the substrate and includes a first emission area defined by the bank; a second light emitting diode which is disposed on the substrate, includes a second emission area defined by the bank, and emits the same color light as the first light emitting diode; an interlayer insulating layer which covers the first light emitting diode and the second light emitting diode and includes a groove or a hole on a top surface overlapping the bank; a barrier layer which is disposed along the groove or hole on the interlayer insulating layer; a first optical member which is disposed on the interlayer insulating layer, overlaps the first emission area, and abuts an edge of the barrier layer; a second optical member which is disposed on the interlayer insulating layer, overlaps the second emission area, and abuts an edge of the barrier layer.

Other detailed matters of the example embodiments of the present disclosure are included in the detailed description and the drawings.

According to the present disclosure, light emitted from the light emitting diode is suppressed from being leaked through the other optical member disposed therearound, rather than an optical member corresponding to the light emitting diode.

According to the present disclosure, the degradation of a viewing angle cut-off performance due to light which is emitted from the light emitting diode, but is leaked through a peripheral optical member can be suppressed.

According to the present disclosure, the light emitted from the light emitting diode is suppressed from being leaked to a peripheral area around the optical member to improve the luminous efficiency.

According to the present disclosure, the luminous efficiency is improved to drive a high quality display device at a lower power.

The effects of the present disclosure are not limited to the aforementioned effects, and other effects, which are not mentioned above, will be apparently understood to a person having ordinary skill in the art from the following description.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an example view of a display device according to one or more example embodiments of the present disclosure;

FIG. 2 is a functional block diagram of a display device according to one or more example embodiments of the present disclosure;

FIG. 3 is a circuit diagram illustrating an example of a pixel circuit included in a display device according to an example embodiment of the present disclosure;

FIG. 4 is an enlarged plan view illustrating placement of an optical member included in a display device according to an example embodiment of the present disclosure;

FIG. 5 is an example of a cross-sectional view taken along line A-A′ of FIG. 4;

FIG. 6 is an example of a cross-sectional view taken along line B-B′ of FIG. 4;

FIG. 7 is a cross-sectional view illustrating an example of a cross-sectional structure of a first optical member included in a display device according to another example embodiment of the present disclosure;

FIG. 8 is a cross-sectional view illustrating an example of a cross-sectional structure of a second optical member included in a display device according to another example embodiment of the present disclosure;

FIG. 9A is a graph illustrating a relative luminance according to a viewing angle of a display device according to Comparative Example of the present disclosure; and

FIG. 9B is a graph illustrating a relative luminance according to a viewing angle of a display device according to another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated. Further, the term “can” fully encompasses all the meanings and coverages of the term “may” and vice versa.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operatively coupled and configured.

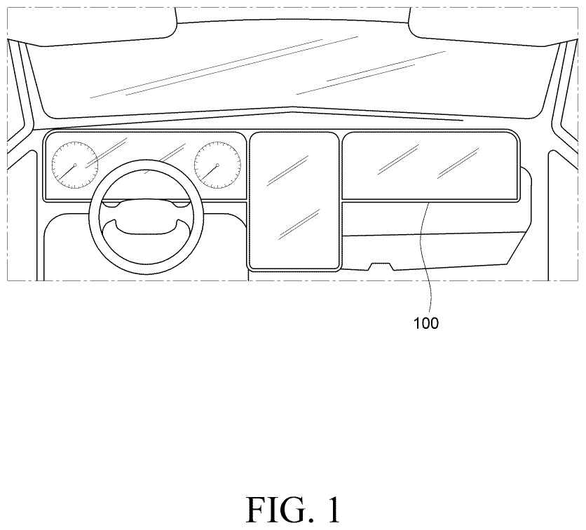

FIG. 1 is an example view of a display device according to one or more example embodiments of the present disclosure.

Referring to FIG. 1, a display device 100 can be disposed in at least a part of a dash board of a vehicle. The dash board of the vehicle can include a configuration disposed in a front surface of front seats (for example, a driver seat and a front passenger seat) of the vehicle. For example, on the dash board of the vehicle, an input configuration for manipulating various functions (for example, an air-conditioner, an audio system, or a navigation system) in the vehicle can be disposed.

The display device 100 is disposed on the dash board of the vehicle to operate as an input unit which manipulates at least a part of various functions of the vehicle. The display device 100 can provide various information related to the vehicle, for example, operation information of the vehicle (for example, a current speed of the vehicle, a remaining fuel amount, or a mileage) or information about parts of the vehicle (for example, a damage level of a vehicle tire).

The display device 100 can be disposed across the driver seat and the front passenger seat disposed in the front seats of the vehicle. A user of the display device 100 can include a driver of the vehicle and a passenger riding on the front passenger seat. Both the vehicle driver and the passenger can use the display device 100.

A part of the display device 100 can be illustrated in FIG. 1. The display device 100 illustrated in FIG. 1 can represent a display panel, among various configurations included in the display device 100. Specifically, for example, the display device 100 illustrated in FIG. 1 can represent at least a part of an active area and a non-active area of the display panel. Among the configurations of the display device 100, configurations other than the parts illustrated in FIG. 1 can be mounted inside the vehicle (or at least a part of the inside of the vehicle).

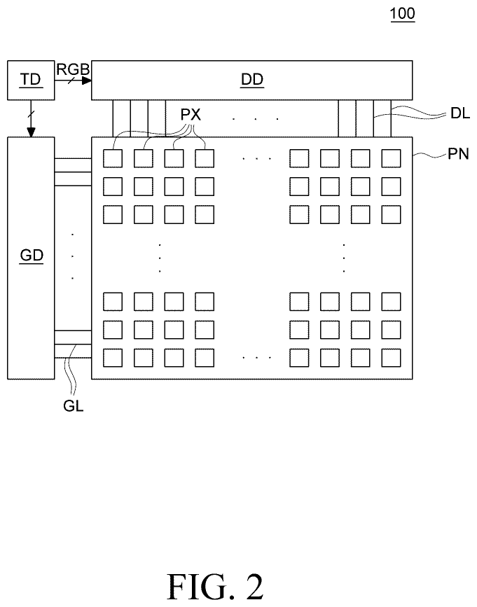

FIG. 2 is a functional block diagram of a display device according to one or more example embodiments of the present disclosure.

As the display device according to the example embodiments of the present disclosure, an electroluminescent display can be applied. The electroluminescent display device can use an organic light emitting diode (OLED) display device, a quantum dot (QD) light emitting diode display device, or an inorganic light emitting diode display device.

Referring to FIG. 2, the display device 100 can include a display panel PN, a data driving circuit DD, a gate driving circuit GD, and a timing controller TD.

The display panel PN can generate images to be provided to the user. For example, the display panel PN can generate and display images to be provided to the user through a plurality of pixels PX in which the pixel circuits are disposed.

The data driving circuit DD, the gate driving circuit GD, and the timing controller TD can provide signals for operations of each pixel PX through signal lines. For example, signal lines for supplying a signal for an operation of each pixel PX can include a plurality of data lines DL and a plurality of gate lines GL.

The plurality of data lines DL is disposed in a column direction and can include a plurality of wiring lines connected to pixels PX disposed in one column direction and the plurality of gate lines GL is disposed in a row direction and can include a plurality of wiring lines connected to pixels PX disposed in one row direction.

In some cases, the display device 100 can further include a power unit. In this case, a signal for an operation of the pixel PX can be supplied through the power line which connects the power unit and the display panel PN. According to the example embodiment, the power unit can supply a power to the data driving circuit DD and the gate driving circuit GD. The data driving circuit DD and the gate driving circuit GD can be driven based on the power supplied from the power unit.

For example, the data driving circuit DD applies a data signal to each pixel PX through the plurality of data lines DL. The gate driving circuit GD applies a gate signal to each pixel PX through the plurality of gate lines GL. The power unit can supply a power voltage to each pixel PX through the power voltage supply lines.

The timing controller TD can control the data driving circuit DD and the gate driving circuit GD. For example, the timing controller TD redisposes digital video data input from the outside in accordance with a resolution of the display panel PN to supply the digital video data to the data driving circuit DD.

The data driving circuit DD converts digital video data input from the timing controller TD into an analog data voltage based on the data control signal to supply the converted analog data voltage to the plurality of data lines DL.

The gate driving circuit GD can generate a scan signal and an emission signal based on the gate control signal. For example, the gate driving circuit GD can include a scan driver and an emission signal driver. The scan driver generates a scan signal in a row sequential manner to drive at least one or more scan lines connected to each pixel row to supply the scan signal to the scan lines. The emission signal driver generates an emission signal in a row sequential manner to drive at least one or more emission signal lines connected to each pixel row to supply the emission signal to the emission signal lines.

According to the example embodiment, the gate driving circuit GD can be disposed in the display panel PN in a gate-driver in panel (GIP) manner. For example, the gate driving circuit GD is divided into a plurality of circuits to be disposed on at least two side surfaces of the display panel PN.

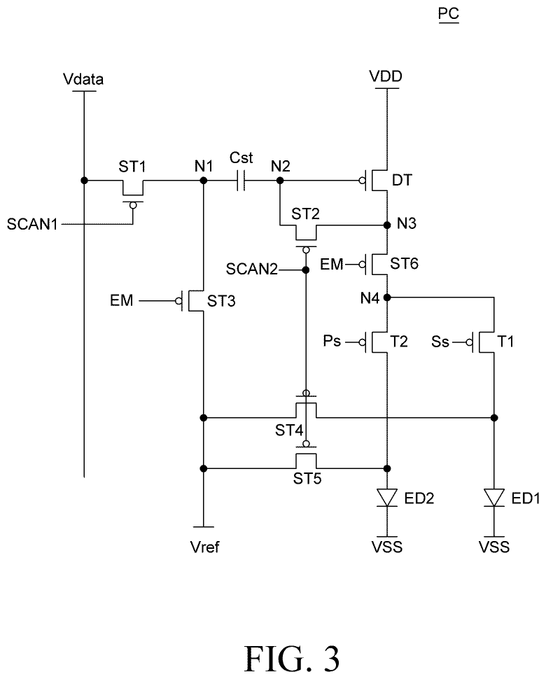

FIG. 3 is a circuit diagram illustrating an example of a pixel circuit included in a display device according to an example embodiment of the present disclosure.

In the meantime, the pixel circuit PC illustrated in FIG. 3 indicates an example embodiment of a pixel circuit corresponding to each of the plurality of pixels PX included in the display device 100 which has been described with reference to FIG. 2.

Referring to FIG. 3, at least some of the plurality of transistors included in the pixel circuit PC can be an n-type transistor or a p-type transistor. In the case of the p-type transistor, a low level voltage of each driving signal refers to a voltage which turns on a TFT and a high level voltage of each driving signal can refer to a voltage which turns off the TFT.

Here, the low level voltage can correspond to a predetermined voltage which is lower than the high level. For example, the low level voltage can include a voltage corresponding to a range of −8 V to −12 V. The high level voltage can correspond to a predetermined voltage which is higher than the low level voltage. For example, the high level voltage can include a voltage corresponding to the range of 12 V to 16 V. According to the example embodiment, the low level voltage is referred to as a first voltage and the high level voltage can be referred to as a second voltage. In this case, the first voltage can be lower than the second voltage.

The pixel circuit PC can include a driving transistor DT, a plurality of switching transistors ST1 to ST6, a first transistor T1, a second transistor T2, a storage capacitor Cst, and a plurality of light emitting diodes ED1 and ED2.

The driving transistor DT can control a driving current applied to the plurality of light emitting diodes ED1 and ED2 in accordance with a source-gate voltage. The driving transistor DT can include a source electrode connected to a high potential power line which supplies a high potential power voltage VDD, a gate electrode connected to a second node N2, and a drain electrode connected to a third node N3.

The first switching transistor ST1 can apply a data voltage Vdata from the data line DL to a first node N1. The first switching transistor ST1 can include a source electrode connected to the data line DL, a drain electrode connected to the first node N1, and a gate electrode connected to a first scan signal line to which a first scan signal SCAN1 is applied. The first switching transistor ST1 can be turned on or turned off by the first scan signal SCAN1. Accordingly, the first switching transistor ST1 can apply a data voltage Vdata from the data line DL to the first node N1, in response to a low level of first scan signal SCAN1 which is a turn-on level.

The second switching transistor ST2 can diode-connect the gate electrode and the drain electrode of the driving transistor DT. The second switching transistor ST2 can include a drain electrode connected to a second node N2, a source electrode connected to a third node N3, and a gate electrode connected to a second scan signal line to which a second scan signal SCAN2 is applied. The second switching transistor ST2 can be turned on or turned off by the second scan signal SCAN2. Therefore, the second switching transistor ST2 can diode-connect the gate electrode and the drain electrode of the driving transistor DT in response to a low level of second scan signal SCAN2 which is a turn-on level.

The third switching transistor ST3 can apply a reference voltage Vref to the first node N1. The third switching transistor ST3 includes a source electrode which is connected to the reference voltage line which supplies the reference voltage Vref, a drain electrode which is connected to the first node N1, and a gate electrode which is connected to the emission signal line to which the emission signal EM is applied. The third switching transistor ST3 can be turned on or turned off by the emission signal EM. Accordingly, the third switching transistor ST3 can transmit the reference voltage Vref to the first node N1 in response to a low level of emission signal EM which is a turn-on level.

The fourth switching transistor ST4 can apply the reference voltage Vref to the anode electrode of the first light emitting diode ED1. The fourth switching transistor ST4 can include a source electrode connected to the reference voltage line which supplies the reference voltage Vref, a drain electrode connected to the anode electrode of the first light emitting diode ED1, and a gate electrode connected to a second scan signal line to which a second scan signal SCAN2 is applied. The fourth switching transistor ST4 can be turned on or turned off by the second scan signal SCAN2. Therefore, the fourth switching transistor ST4 can apply the reference voltage Vref to the anode electrode of the first light emitting diode ED1 in response to the low level of second scan signal SCAN2 which is a turn-on level.

The fifth switching transistor ST5 can apply the reference voltage Vref to the anode electrode of the second light emitting diode ED2. The fifth switching transistor ST5 can include a source electrode connected to the reference voltage line which supplies the reference voltage Vref, a drain electrode connected to the anode electrode of the second light emitting diode ED2, and a gate electrode connected to a second scan signal line to which a second scan signal SCAN2 is applied. The fifth switching transistor ST5 can be turned on or turned off by the second scan signal SCAN2. Therefore, the fifth switching transistor ST5 can apply the reference voltage Vref to the anode electrode of the second light emitting diode ED2 in response to the low level of second scan signal SCAN2 which is a turn-on level.

The sixth switching transistor ST6 can form a current path between the driving transistor DT and any one light emitting diode among the plurality of light emitting diodes ED1 and ED2. The sixth switching transistor ST6 can include a source electrode connected to the third node N3, a drain electrode connected to the fourth node N4, and a gate electrode connected to the emission signal line to which an emission signal EM is applied. The sixth switching transistor ST6 can be turned on or turned off by the emission signal EM. Therefore, the sixth switching transistor ST6 electrically connects the third node N3 and the fourth node N4 in response to a low level of emission signal EM which is a turn-on level to form a current path between the driving transistor DT and any one light emitting diode among the plurality of light emitting diodes ED1 and ED2.

The storage capacitor Cst can include a first electrode connected to the first node N1 and a second electrode connected to the second node N2. One electrode of the storage capacitor Cst is connected to the gate electrode of the driving transistor DT and the other electrode of the storage capacitor Cst can be connected to the first switching transistor ST1. The storage capacitor Cst stores a predetermined voltage to constantly maintain a voltage of the gate electrode of the driving transistor DT while any one of the plurality of light emitting diodes ED1 and ED2 emits light.

The first transistor T1 generates a current path of a first driving current which passes through the first light emitting diode ED1 and the second transistor T2 can generate a current path of a second driving current which passes through the second light emitting diode ED2.

The first transistor T1 is connected between the fourth node N4 and the first light emitting diode ED1 and a gate electrode of the first transistor T1 can be connected to a first mode signal line which supplies a first mode signal Ss. When the pixel PX to which the pixel circuit PC is applied is driven in a first mode which is a wide field-of-view mode, the first mode signal Ss is supplied to the gate electrode of the first transistor T1 to turn on the first transistor T1. Therefore, a current path of the first driving current which passes through the first light emitting diode ED1 is formed so that the first light emitting diode ED1 can emit light. In the meantime, the first transistor T1 can be referred to as a first emission control transistor which controls emission of the first light emitting diode ED1.

The second transistor T2 is connected between the fourth node N4 and the second light emitting diode ED2 and a gate electrode of the second transistor T2 can be connected to a second mode signal line which supplies a second mode signal Ps. When the pixel PX to which the pixel circuit PC is applied is driven in a second mode which is a narrow field-of-view mode, the second mode signal Ps is supplied to the gate electrode of the second transistor T2 to turn on the second transistor T2. Therefore, a current path of the second driving current which passes through the second light emitting diode ED2 is formed so that the second light emitting diode ED2 can emit light. In the meantime, the second transistor T2 can be referred to as a second emission control transistor which controls emission of the second light emitting diode ED2.

The first light emitting diode ED1 can be connected between the first transistor T1 which is turned on or turned off by the first mode signal Ss and the low potential power line which supplies a low potential power voltage VSS. The second light emitting diode ED2 can be connected between the second transistor T2 which is turned on or turned off by the second mode signal Ps and the low potential power line which supplies a low potential power voltage VSS.

In this case, the first light emitting diode ED1 or the second light emitting diode ED2 can be connected to another configuration of the pixel circuit PC, for example, the driving transistor DT, by the first transistor T1 or the second transistor T2 which is turned on according to a driving mode. For example, the first light emitting diode ED1 is connected to the driving transistor DT via the first transistor T1 which is turned on in the first mode and can supply light by the first driving current, in the first mode, for example, in the wide field-of-view mode at a wide viewing angle which is a first viewing angle. Further, the second light emitting diode ED2 is connected to the driving transistor DT via the second transistor T2 which is turned on in the second mode and can supply light by the second driving current, in the second mode, for example, in the narrow field-of-view mode at a narrow viewing angle which is a second viewing angle. Here, the driving mode is specified by the user's input or determined when a predetermined condition is satisfied.

In the first mode, only the first light emitting diode ED1 emits light and in the second mode, only the second light emitting diode ED2 can emit light. Here, the second mode signal Ps which controls the emission of the second light emitting diode ED2 to allow only the first light emitting diode ED1 to emit light in the first mode can be output only at a high level which is a turn-off level. Further, the first mode signal Ss which controls the emission of the first light emitting diode ED1 to allow only the second light emitting diode ED2 to emit light in the second mode can be output only at a high level which is a turn-off level.

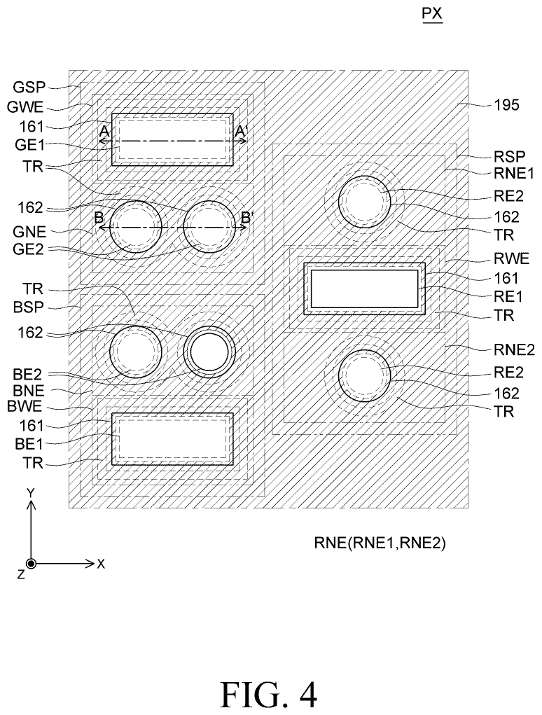

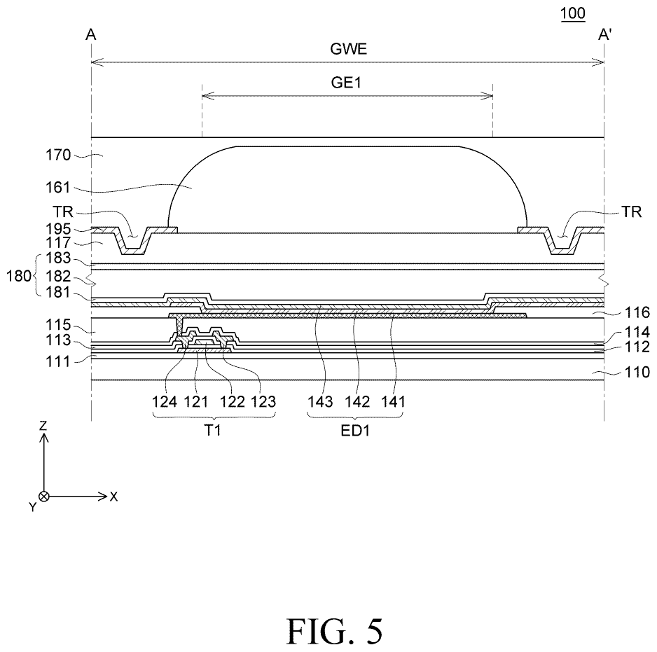

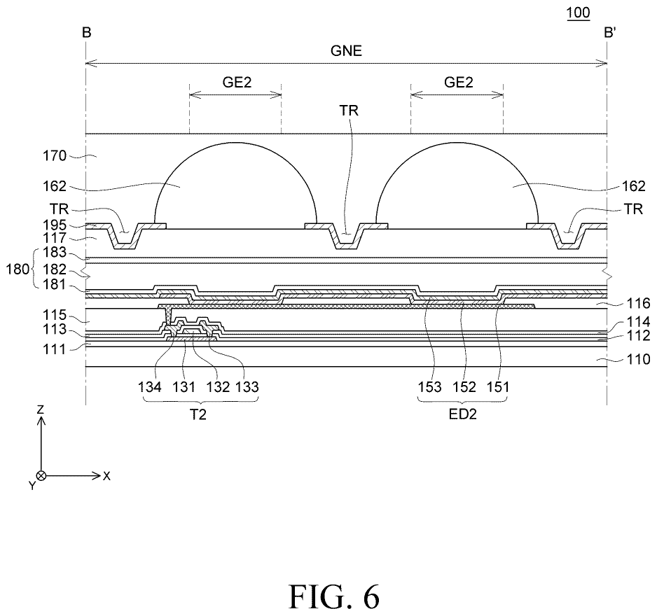

FIG. 4 is an enlarged plan view illustrating placement of an optical member included in a display device according to an example embodiment of the present disclosure. FIG. 5 is a cross-sectional view illustrating an example taken along line A-A′ of FIG. 4. FIG. 6 is a cross-sectional view illustrating an example taken along line B-B′ of FIG. 4.

Particularly, FIG. 4 illustrates a plan view of a pixel PX when the pixel PX includes three sub pixels, for example, a first sub pixel RSP, a second sub pixel GSP, and a third sub pixel BSP.

Further, FIG. 5 illustrates a pixel in which a first optical member 161 is disposed as an example embodiment of a display device 100 taken along line A-A′ of FIG. 4 and FIG. 6 illustrates a pixel in which a second optical member 162 is disposed as an example embodiment of a display device 100 taken along line B-B′ of FIG. 4.

In FIGS. 5 and 6, for the convenience of description, only a region corresponding to a first optical area GWE and a second optical area GNE of the second sub pixel GSP, among three sub pixels RSP, GSP, and BSP illustrated in FIG. 4, is illustrated. However, the other sub pixels RSP and BSP can also be formed with the same configuration.

In the meantime, for the convenience of description, hereinafter, a horizontal direction in the plan view is illustrated as a first direction X and a vertical direction in the plan view is illustrated as a second direction Y. Further, a normal direction of a plane surface defined by the first direction X and the second direction Y, for example, a thickness direction of the display device 100 can be defined as a third direction Z.

Referring to FIG. 4, the pixel PX can include a plurality of sub pixels RSP, GSP, and BSP which represents different colors. For example, the pixel PX can include a first sub pixel RSP which implements red, a second sub pixel GSP which implements green, and a third sub pixel BSP which implements blue. According to the example embodiment, a first sub pixel RSP is referred to as a red sub pixel, a second sub pixel GSP is referred to as a green sub pixel, and a third sub pixel BSP can be referred to as a blue sub pixel. In each of the plurality of sub pixels RSP, GSP, and BSP included in the pixel PX, the pixel circuit PC which has been described with reference to FIG. 3 can be disposed.

The plurality of sub pixels RSP, GSP, and BSP can include first optical areas RWE, GWE, and BWE and second optical areas RNE, GNE, and BNE which provide different viewing angles, respectively.

The first optical areas RWE, GWE, and BWE of the sub pixels RSP, GSP, and BSP operate independently from the second optical areas RNE, GNE, and BNE of the corresponding pixels PX. For example, each sub pixel RSP, GSP, and BSP can include a first light emitting diode ED1 disposed in the first optical area RWE, GWE, and BWE of a corresponding sub pixel RSP, GSP, and BSP and a second light emitting diode ED2 disposed in the second optical area RNE, GNE, and BNE of a corresponding sub pixel RSP, GSP, and BSP.

At least some of the plurality of sub pixels RSP, GSP, and BSP includes a plurality of second optical areas RNE, GNE, and BNE. For example, the first sub pixel RSP can include one first optical area RWE and a plurality of second optical areas RNE1 and RNE2. At this time, the first optical area RWE can be disposed between the plurality of second optical areas RNE1 and RNE2. For example, in the second direction Y, one second optical area RNE2, a first optical area RWE, and the other second optical area RNE2 can be sequentially disposed, but the present disclosure is not limited thereto.

In one pixel PX, the first light emitting diode ED1 and the second light emitting diode ED2 can be disposed in every first optical area RWE, GWE, BWE and every second optical area RNE, GNE, BNE of the plurality of sub pixels RSP, GSP, and BSP, respectively.

For example, in one pixel PX, a first light emitting diode ED1 disposed in the first optical area RWE of the first sub pixel RSP, a second light emitting diode ED2 disposed in the second optical area RNE of the first sub pixel RSP, a first light emitting diode ED1 disposed in the first optical area GWE of the second sub pixel GSP, a second light emitting diode ED2 disposed in the second optical area GNE of the second sub pixel GSP, a first light emitting diode ED1 disposed in the first optical area BWE of the third sub pixel BSP, a second light emitting diode ED2 disposed in the second optical area BNE of the third sub pixel BSP can be disposed.

In the first optical area RWE, GWE, and BWE of each sub pixel RSP, GSP, and BSP, at least one first optical member 161 disposed so as to overlap the first emission area RE1, GE1, and BE1 of the first light emitting diode ED1 can be disposed. In the second optical area RNE, GNE, and BNE of each sub pixel RSP, GSP, and BSP, at least one second optical member 162 disposed so as to overlap the second emission area RE2, GE2, and BE2 of the second light emitting diode ED2 can be disposed. At this time, the first optical areas RWE, GWE, and BWE have a first viewing angle and the second optical areas RNE, GNE, and BNE have a second viewing angle which is smaller than the first viewing angle.

In the meantime, in each sub pixel RSP, GSP, and BSP, the first light emitting diode ED1 and the second light emitting diode ED2 can be disposed in different manners. For example, in the first sub pixel RSP, one second light emitting diode ED2, the first light emitting diode ED1, and the other second light emitting diode ED2 can be sequentially disposed in the second direction Y. In contrast, in the second sub pixel GSP, the plurality of second light emitting diodes ED2 is disposed in the second optical area GNE and one first light emitting diode ED1 can be disposed in the first optical area GWE. At this time, the plurality of second light emitting diodes ED2 can be disposed on the same line in the first direction X. Further, the first light emitting diode ED1 and the plurality of second light emitting diodes ED2 can be disposed so as to overlap each other in the second direction Y. Further, in the second sub pixel GSP, the plurality of second light emitting diodes ED2 can be disposed below the first light emitting diode ED1. Next, in the third sub pixel BSP, the plurality of second light emitting diodes ED2 is disposed in the second optical area BNE and one first light emitting diode ED1 can be disposed in the first optical area BWE. At this time, the plurality of second light emitting diodes ED2 can be disposed on the same line in the first direction X. Further, the first light emitting diode ED1 and the plurality of second light emitting diodes ED2 can be disposed so as to overlap each other in the second direction Y. Further, in the third sub pixel BSP, the plurality of second light emitting diodes ED2 can be disposed above the first light emitting diode ED1. However, this is just an example so that the placement of the first light emitting diode ED1 and the second light emitting diode ED2 in each sub pixel RSP, GSP, and BSP is not limited thereto.

Referring to FIGS. 5 and 6 together, the display device 100 according to the example embodiment of the present disclosure can include a substrate 110, a buffer film 111, a gate insulating layer 112, a first interlayer insulating layer 113, a lower protection film 114, an overcoat layer 115, a bank 116, a first transistor T1, a second transistor T2, a first light emitting diode ED1, a second light emitting diode ED2, an encapsulation member 180, a second interlayer insulating layer 117, a barrier layer 195, a first optical member 161, a second optical member 162, and an optical member protection film 170.

The substrate 110 can include an insulating material. The substrate 110 can include a transparent material. For example, the substrate 110 can include glass or plastic.

The buffer film 111 can be disposed on the substrate 110. The buffer film 111 can include an insulating material. For example, the buffer film 111 can include an inorganic insulating material, such as silicon oxide (SiOx) or silicon nitride (SiNx). The buffer film 111 can have a multi-layered structure. For example, the buffer film 111 can have a laminated structure of a film formed of silicon nitride (SiNx) and a film formed of silicon oxide (SiOx).

The buffer film 111 can be located between the substrate 110 and a driving part of each sub pixel RSP, GSP, and BSP. The buffer film 111 can suppress the contamination due to the substrate 110 in a process of forming the driving part. For example, a top surface of the substrate 110 which faces the driving part of each sub pixel RSP, GSP, and BSP can be covered by the buffer film 111. The driving part of each sub pixel RSP, GSP, and BSP can be disposed on the buffer film 111.

The gate insulating layer 112 can be disposed on the buffer film 111. The gate insulating layer 112 can include an insulating material. For example, the gate insulating layer 112 can include an inorganic insulating material, such as silicon oxide (SiO) or silicon nitride (SiN). The gate insulating layer 112 can include a material having a high permittivity. For example, the gate insulating layer 112 can include a High-K material, such as hafnium oxide (HfO). The gate insulating layer 112 can have a multi-layered structure.

The first interlayer insulating layer 113 can be disposed on the gate insulating layer 112. The first interlayer insulating layer 113 can include an insulating material. For example, the first interlayer insulating layer 113 can include an inorganic insulating material, such as silicon oxide (SiO) or silicon nitride (SiN). The first interlayer insulating layer 113 can extend between the gate electrodes 122 and 132 and the source electrodes 123 and 133 of the transistors T1 and T2 and between the gate electrodes 122 and 132 and the drain electrodes 124 and 134. For example, the source electrodes 123 and 133 and the drain electrodes 124 and 134 of the first transistor T1 and the second transistor T2 can be insulated from the gate electrodes 122 and 132 by the first interlayer insulating layer 113. The first interlayer insulating layer 113 can cover the gate electrodes 122 and 132 of the first transistor T1 and the second transistor T2. The source electrodes 123 and 133 and the drain electrodes 124 and 134 of each sub pixel RSP, GSP, and BSP can be located on the first interlayer insulating layer 113. The gate insulating layer 112 and the first interlayer insulating layer 113 can expose a source region and a drain region of each semiconductor layer 121, 131 located in each sub pixel RSP, GSP, and BSP.

The lower protection film 114 can be disposed on the first interlayer insulating layer 113. The lower protection film 114 can include an insulating material. For example, the lower protection film 114 can include an inorganic insulating material, such as silicon oxide (SiO) or silicon nitride (SiN).

The lower protection film 114 can suppress the damage of the driving part due to the external moisture and shocks. The lower protection film 114 can extend along surfaces of the first transistor T1 and the second transistor T2. The lower protection film 114 is in contact with the first interlayer insulating layer 113 at the outside of the driving part located in each sub pixel RSP, GSP, and BSP.

The overcoat layer 115 can be disposed on the lower protection film 114. The overcoat layer 115 can include an insulating material. The overcoat layer 115 can include a material different from that of the lower protection film 114. For example, the overcoat layer 115 can include an organic insulating material.

The overcoat layer 115 can remove a step caused by the driving part of each sub pixel RSP, GSP, and BSP. For example, a top surface of the overcoat layer 115 which is opposite to the substrate 110 can be a flat surface.

The first transistor T1 and the second transistor T2 can be disposed on the substrate 110. The first transistor T1 can be electrically connected between the drain electrode of the driving transistor DT and the first lower electrode 141 of the first light emitting diode ED1. The second transistor T2 can be electrically connected between the drain electrode of the driving transistor DT and the second lower electrode 151 of the second light emitting diode ED2.

The first transistor T1 can include a first semiconductor layer 121, a first gate electrode 122, a first source electrode 123, and a first drain electrode 124. The first transistor T1 can have the same structure as the switching transistor and the driving transistor.

For example, the first semiconductor layer 121 is located between the buffer film 111 and the gate insulating layer 112 and the first gate electrode 122 can be located between the gate insulating layer 112 and the first interlayer insulating layer 113. The first source electrode 123 and the first drain electrode 124 can be located between the first interlayer insulating layer 113 and the lower protection film 114. The first gate electrode 122 can overlap a channel region of the first semiconductor layer 121. The first source electrode 123 can be electrically connected to the source region of the first semiconductor layer 121. The first drain electrode 124 can be electrically connected to the drain region of the first semiconductor layer 121.

The second transistor T2 can include a second semiconductor layer 131, a second gate electrode 132, a second source electrode 133, and a second drain electrode 134. For example, the second semiconductor layer 131 is located on the same layer as the first semiconductor layer 121 and the second gate electrode 132 is located on the same layer as the first gate electrode 122. The second source electrode 133 and the second drain electrode 134 can be located on the same layer as the first source electrode 123 and the first drain electrode 124.

The first light emitting diode ED1 and the second light emitting diode ED2 of each sub pixel RSP, GSP, and BSP can be located on the overcoat layer 115 of each sub pixel RSP, GSP, and BSP. For example, the first lower electrode 141 of the first light emitting diode ED1 is electrically connected to the first drain electrode 124 or the first source electrode 123 of the first transistor T1 through a contact hole which passes through the lower protection film 114 and the overcoat layer 115. A second lower electrode 151 of the second light emitting diode ED2 can be electrically connected to the second drain electrode 134 or the second source electrode 133 of the second transistor T2 through a contact hole which passes through the lower protection film 114 and the overcoat layer 115.

The first light emitting diode ED1 can emit light representing a specific color. For example, the first light emitting diode ED1 can include a first lower electrode 141, a first emission layer 142, and a first upper electrode 143 which are sequentially laminated on the substrate 110.

The first lower electrode 141 can include a conductive material. The first lower electrode 141 can include a material having a high reflectance. For example, the first lower electrode 141 includes metal, such as aluminum (Al), or silver (Ag). The first lower electrode 141 can have a multi-layered structure. For example, the first lower electrode 141 can have a structure in which a reflective electrode formed of a metal is located between transparent electrodes formed of a transparent conductive material, such as ITO and IZO. The first lower electrode 141 can be electrically connected to the first drain electrode 124 of the first transistor T1 through a contact hole which passes through the lower protection film 114 and the overcoat layer 115.

The first emission layer 142 can generate light with luminance corresponding to a voltage difference between the first lower electrode 141 and the first upper electrode 143. For example, the first emission layer 142 can include an emission material layer (EML) including an emission material. The emission material can include an organic material, an inorganic material, or a hybrid material.

The first emission layer 142 can have a multi-layered structure. For example, the first emission layer 142 can further include at least one of a hole injection layer HIL, a hole transport layer HTL, an electron transport layer ETL, and an electron injection layer EIL.

The first upper electrode 143 can include a conductive material. The first upper electrode 143 can include a different material from that of the first lower electrode 141. A transmittance of the first upper electrode 143 can be higher than a transmittance of the first lower electrode 141. For example, the first upper electrode 143 can be a transparent electrode formed of a transparent conductive material, such as ITO and IZO. Accordingly, in the display device 100 according to the example embodiment of the present disclosure, light generated by the first emission layer 142 can be emitted through the first upper electrode 143.

The second light emitting diode ED2 can implement the same color as the first light emitting diode ED1 disposed in the same sub pixel RSP, GSP, and BSP. For example, the second light emitting diode ED2 can include a second lower electrode 151, a second emission layer 152, and a second upper electrode 153 which are sequentially laminated on the substrate 110.

The second lower electrode 151 corresponds to the first lower electrode 141, the second emission layer 152 corresponds to the first emission layer 142, and the second upper electrode 153 can correspond to the first upper electrode 143. For example, the second lower electrode 151 can be formed for the second light emitting diode ED2 with the same structure as the first lower electrode 141 and this is the same for the second emission layer 152 and the second upper electrode 153. For example, the first light emitting diode ED1 and the second light emitting diode ED2 can be formed to have the same structure. However, it is not limited thereto and in some cases, at least a partial configuration of the first light emitting diode ED1 and the second light emitting diode ED2 can be formed to be different.

The second emission layer 152 can be spaced apart from the first emission layer 142. Therefore, in the display device according to the example embodiment of the present disclosure, light emission by a leakage current can be suppressed.

In the display device, light can be generated by only one of the first emission layer 142 and the second emission layer 152 by the user's choice or according to a predetermined condition.

The second lower electrode 151 of each sub pixel RSP, GSP, and BSP can be spaced apart from the first lower electrode 141 of the corresponding sub pixel RSP, GSP, and BSP. For example, the bank 116 can be disposed between the first lower electrode 141 and the second lower electrode 151 of each sub pixel RSP, GSP, and BSP. The bank 116 can include an insulating material. For example, the bank 116 can include an organic insulating material. The bank 116 can include a material different from that of the overcoat layer 115.

The second lower electrode 151 of each sub pixel RSP, GSP, and BSP can be insulated from the first lower electrode 141 of the corresponding sub pixel RSP, GSP, and BSP by the bank 116. For example, the bank 116 can cover an edge of the first lower electrode 141 and an edge of the second lower electrode 151 located in each sub pixel RSP, GSP, and BSP.

The bank 116 can divide the first emission areas RE1, GE1, and BE1 of the first light emitting diode ED1 and the second emission areas RE2, GE2, and BE2 of the second light emitting diode ED2. For example, the first emission areas RE1, GE1, and BE1 of the first light emitting diode ED1 can be a partial area of the first lower electrode 141 which is exposed by the bank 116. The second emission areas RE2, GE2, and BE2 of the second light emitting diode ED2 can be a partial area of the second lower electrode 151 which is exposed by the bank 116. At this time, referring to FIG. 4, a size of the first emission areas RE1, GE1, and BE1 of the first light emitting diode ED1 divided in each sub pixel RSP, GSP, and BSP can be larger than a size of the second emission areas RE2, GE2, and BE2 of the second light emitting diode ED2, but is not limited thereto.

The first emission layer 142 and the first upper electrode 143 of the first light emitting diode ED1 located in each sub pixel RSP, GSP, and BSP can be laminated on a partial area of the first lower electrode 141 exposed by the bank 116. Specifically, the first emission layer 142 and the first upper electrode 143 can be laminated on the first emission areas RE1, GE1, and BE1 exposed by the bank 116 and the bank 116. The second emission layer 152 and the second upper electrode 153 of the second light emitting diode ED2 located in each sub pixel RSP, GSP, and BSP can be laminated on a partial area of the second lower electrode 151 exposed by the bank 116. Specifically, the second emission layer 152 and the second upper electrode 153 can be laminated on the second emission areas RE2, GE2, and BE2 exposed by the bank 116 and the bank 116.

The second upper electrode 153 of each sub pixel RSP, GSP, and BSP can be electrically connected to the first upper electrode 143 of the corresponding sub pixel RSP, GSP, and BSP. For example, a voltage applied to the second upper electrode 153 of the second light emitting diode ED2 located in each sub pixel RSP, GSP, and BSP is equal to a voltage applied to the first upper electrode 143 of the first light emitting diode ED1 located in the corresponding sub pixel RSP, GSP, and BSP. The second upper electrode 153 of each sub pixel RSP, GSP, and BSP can include the same material as the first upper electrode 143 of the corresponding sub pixel RSP, GSP, and BSP. For example, the second upper electrode 153 of each sub pixel RSP, GSP, and BSP can be formed simultaneously with the first upper electrode 143 of the corresponding sub pixel RSP, GSP, and BSP. The second upper electrode 153 of each sub pixel RSP, GSP, and BSP extends onto the bank 116 to be in direct contact with the first upper electrode 143 of the corresponding sub pixel RSP, GSP, and BSP. Luminance of the first optical areas RWE, GWE, and BWE and luminance of the second optical areas RNE, GNE, and BNE located in each sub pixel RSP, GSP, and BSP can be controlled by a driving current generated in the corresponding sub pixel RSP, GSP, and BSP.

The encapsulation member 180 can be located on the first light emitting diode ED1 and the second light emitting diode ED2 of each sub pixel RSP, GSP, and BSP. The encapsulation member 180 can suppress the damage of the light emitting diodes ED1 and ED2 due to moisture and shocks from the outside. The encapsulation member 180 can have a multi-layered structure. For example, the encapsulation member 180 can include a first encapsulation layer 181, a second encapsulation layer 182, and a third encapsulation layer 183 which are sequentially laminated, but the example embodiments of the present disclosure are not limited thereto.

The first encapsulation layer 181, the second encapsulation layer 182, and the third encapsulation layer 183 can include an insulating material. The second encapsulation layer 182 can include a material different from that of the first encapsulation layer 181 and the third encapsulation layer 183. For example, the first encapsulation layer 181 and the third encapsulation layer 183 are inorganic encapsulation layers including an inorganic insulating material and the second encapsulation layer 182 can include an organic encapsulation layer including an organic insulating material. Therefore, the light emitting diodes ED1 and ED2 of the display device 100 can efficiently suppress the damage due to the moisture and shocks from the outside.

The second interlayer insulating layer 117 can be disposed on the encapsulation member 180. The second interlayer insulating layer 117 is disposed between the encapsulation member 180 and the barrier layer 195 to insulate the barrier layer 195.

The second interlayer insulating layer 117 includes a trench structure TR on a top surface. For example, the trench structure TR can have a groove concave from the top surface of the second interlayer insulating layer 117. Therefore, the trench structure TR can have a shape in which only a part of the overall thickness of the second interlayer insulating layer 117 is dented.

The trench structure TR can be disposed to be adjacent to the first optical member 161 and the second optical member 162. For example, the trench structure TR can be disposed so as to enclose (each of) the first optical member 161 and the second optical member 162 in a plan view. Therefore, the trench structure TR can be disposed so as not to overlap the first optical member 161 and the second optical member 162. Further, the trench structure TR can be disposed between the plurality of second optical members 162 disposed in each of the second optical areas RNE, GNE, and BNE.

The trench structure TR can be disposed so as not to overlap the first emission areas RE1, GE1, and BE1 and the second emission areas RE2, GE2, and BE2. For example, the trench structure TR can be disposed above the bank 116 so as to overlap the bank 116. At this time, the trench structure TR can be disposed so as not to extend beyond the bank 116. Therefore, the trench structure TR may not interfere with a normal path of light emitted from the first light emitting diode ED1 and the second light emitting diode ED2. At this time, when it is described with the first light emitting diode ED1 as an example, the normal path of the light means a path through which light generated from the first light emitting diode ED1 is discharged through the first optical member 161 which is disposed so as to correspond to the first light emitting diode.

The second interlayer insulating layer 117 can include an insulating material. For example, the second interlayer insulating layer 117 can include an organic insulating material or an inorganic insulating material, but is not limited thereto.

The barrier layer 195 disposed along the trench structure TR is located on the second interlayer insulating layer 117. The barrier layer 195 can be disposed above the first light emitting diode ED1 and the second light emitting diode ED2 in the active area. The barrier layer 195 can be disposed so as to cover the entire trench structure TR. For example, the barrier layer 195 can be disposed so as to entirely cover side surfaces and a top surface of the second interlayer insulating layer 117 exposed by the trench structure TR.

The barrier layer 195 can be disposed so as not to overlap the first emission areas RE1, GE1, and BE1 and the second emission areas RE2, GE2, and BE2. Therefore, the barrier layer 195 can include areas which are at least partially spaced apart from each other, on the second interlayer insulating layer 117. As described above, the barrier layer 195 can be disposed so as not to interfere with a normal traveling path of light generated by the first light emitting diode ED1 and the second light emitting diode ED2.

The barrier layer 195 can be disposed so as to overlap the bank 116. The barrier layer 195 can limit an abnormal path of light generated by the first light emitting diode ED1 and the second light emitting diode ED2. For example, the plurality of barrier layers 195 can block light which travels around the corresponding first optical member 161 and second optical member 162, among light emitted from the first emission areas RE1, GE1, and BE1 and the second emission areas RE2, GE2, and BE2. For example, the barrier layer 195 can block light which is directed to an abnormal path, among light emitted from the first optical areas RWE, GWE, and BWE and the second optical areas RNE, GNE, and BNE located in each sub pixel RSP, GSP, and BSP, together with the first optical member 161 and the second optical member 162. The abnormal path of light in the present disclosure will be described with the first light emitting diode ED1 as an example. The abnormal path of the light means a path through which light generated from the first light emitting diode ED1 is discharged through other first optical member 161 or second optical member 162 adjacent thereto, rather than the first optical member 161 which is disposed on the first light emitting diode ED1 so as to correspond thereto.

A touch electrode can be further disposed on the second interlayer insulating layer 117. The touch electrode can be configured to sense an external touch input using a user's finger or a touch pen.

At this time, the barrier layer 195 can be disposed on the same layer as the touch electrode. Further, a touch bridge electrode can be further disposed on the encapsulation member 180 in addition to the touch electrode, but is not limited thereto. Alternatively, the barrier layer 195 can function as a touch electrode, but is not limited thereto.

The barrier layer 195 can be formed of the same material as the touch electrode. For example, the barrier layer 195 and the touch electrode can include a reflective material. Specifically, the barrier layer 195 and the touch electrode can include a metal material, such as titanium (Ti), aluminum (Al), silver (Ag), copper (Cu), and a magnesium-silver alloy (Mg:Ag), but are not limited thereto.

In the meantime, a touch buffer layer can be further disposed between the encapsulation member 180 and the barrier layer 195, but is not limited thereto.

The plurality of optical members 161 and 162 which cover ends (or edges, especially in a plan view) of the barrier layer 195 is disposed on the second interlayer insulating layer 117. Therefore, ends of each of the plurality of optical members 161 and 162 are disposed on the barrier layer 195. As an alternative embodiment, each optical member can also abut the end (or edge) of the barrier, rather than covering or overlaping the end (or edge) of the barrier layer. Further, the plurality of optical members 161 and 162 is disposed so as to overlap the plurality of light emitting diodes ED1 and ED2. The plurality of optical members 161 and 162 can be disposed so as not to overlap the trench structure TR. For example, ends of the plurality of optical members 161 and 162 may not overlap the trench structure TR.

The plurality of optical members 161 and 162 can include a first optical member 161 extending in the first direction and a second optical member 162 which has a different planar surface shape (a different shape in the plan view) from the first optical member 161. The first optical member 161 and the second optical member 162 can be disposed on the same layer as the barrier layer 195 on the second interlayer insulating layer 117.

The first optical member 161 and the second optical member 162 can overlap the first emission areas RE1, GE1, and BE1 and the second emission areas RE2, GE2, and BE2, respectively. At this time, a center of the first optical member 161 can match a center of the first emission area RE1, GE1, and BE1. Further, a center of the second optical member 162 can match a center of the second emission area RE2, GE2, and BE2, but is not limited thereto.

First, referring to FIG. 5, the first optical member 161 can be disposed above the first light emitting diode ED1. For example, the first optical member 161 can be disposed so as to overlap the first emission areas RE1, GE1, and BE1. Therefore, light generated by the first light emitting diode ED1 of each sub pixel RSP, GSP, and BSP can be emitted through the first optical member 161 disposed in the first optical area RWE, GWE, and BWE of the corresponding sub pixel RSP, GSP, and BSP.

The first optical member 161 has a shape which does not restrict the light to traveling in at least one direction. Referring to FIG. 4 together, a planar surface shape (i.e. a shape in the plan view) of the first optical member 161 located in each sub pixel RSP, GSP, and BSP can have a shape which extends in the first direction X. For example, a planar surface shape of the first optical member 161 can have a bar shape extending in the first direction X. Therefore, the planar surface shape of the first optical member 161 includes a long side extending in the first direction X and a short side which is connected from both ends in the second direction Y. For example, a planar surface shape of the first optical member 161 can be a rectangle with a long side placed in the first direction X.

In this case, a traveling direction of light emitted from the first optical area RWE, GWE, and BWE of each sub pixel RSP, GSP, and BSP may not be limited in the first direction X. For example, contents (or images) provided through the first optical area RWE, GWE, and BWE of each sub pixel RSP, GSP, and BSP can be shared by surrounding people which is adjacent to the user in the first direction X. Accordingly, the contents provided by the light emitted through the first optical member 161 can be provided at a viewing angle which is larger in the first direction X than contents provided by the light emitted through the second optical member 162. For example, the content provided by the light emitted through the first optical member 161 can be provided in a wide field-of-view mode (share mode).

At least a part of a top surface of a cross-sectional shape of the first optical member 161 taken along the first direction X can be flat. Further, both side surfaces of the first optical member 161 can be formed as a curved line or a straight line. For example, referring to FIG. 5, a cross-sectional shape with respect to the long side of the first optical member 161 can be formed by an upper flat surface and a curved line which is connected from both ends of the flat surface to the second interlayer insulating layer 117. Alternatively, for example, a cross-sectional shape with respect to the long side of the first optical member 161 can be formed by an upper flat surface and a straight line which is vertically connected from both ends of the flat surface toward the second interlayer insulating layer 117.

Next, referring to FIG. 6, the second optical member 162 can be disposed above the second light emitting diode ED2. For example, the second optical member 162 can be disposed so as to overlap the second emission areas RE2, GE2, and BE2. Therefore, light generated by the second light emitting diode ED2 of each sub pixel RSP, GSP, and BSP is refracted through the second optical member 162 disposed in the second optical area RNE, GNE, and BNE of a corresponding sub pixel RSP, GPS, and BSP to be emitted. The second optical member 162 limits the traveling of the passing light in the first direction X. For example, a planar surface shape (i.e. a shape in the plan view) of the second optical member 162 located in each sub pixel RSP, GSP, and BSP can be a circular shape. However, it is not limited thereto and a planar surface shape of the second optical member 162 located in each sub pixel RSP, GSP, and BSP can be a polygonal shape.

In this case, traveling of light emitted from the second optical area RNE, GNE, and BNE of each sub pixel RSP, GSP, and BSP can be limited in the first direction X. For example, the contents (or images) provided by the second optical areas RNE, GNE, and BNE of each sub pixel RSP, GSP, and BSP may not be shared by the people around the user. Accordingly, the contents provided by the light emitted through the second optical member 162 can be provided at a viewing angle which is smaller in the left and right than the contents provided by the light emitted through the first optical member 161. For example, the contents provided by the light emitted through the second optical member 162 can be provided in a narrow field-of-view mode (private mode).

A cross-sectional shape of the second optical member 162 taken along the first direction X can be a semicircular shape, but is not limited thereto.

The first emission area RE1, GE1, and BE1 of each pixel PX can have a shape corresponding to the first optical member 161 of the corresponding sub pixel RSP, GSP, and BSP. For example, a planar surface shape (i.e. a shape in the plan view) of the first emission area RE1, GE1, and BE1 of each sub pixel RSP, GSP, and BSP can have a bar shape which extends in the first direction X. The first optical member 161 can have a size larger than the first emission area RE1, GE1, and BE1 of the corresponding sub pixel RSP, GPS, and BSP. Accordingly, efficiency of light emitted from the first emission area RE1, GE1, and BE1 of each sub pixel RSP, GSP, and BSP can be improved.

The second emission area RE2, GE2, and BE2 of each sub pixel RSP, GSP, and BSP can have a shape corresponding to the second optical member 162 of the corresponding sub pixel RSP, GSP, and BSP. For example, a planar surface shape (i.e. a shape in the plan view) of the second emission area RE2, GE2, and BE2 of each sub pixel RSP, GSP, and BSP can have a circular shape or a polygonal shape. The second optical member 162 can have a size larger than the second emission area RE2, GE2, and BE2 of the corresponding sub pixel RSP, GPS, and BSP. Accordingly, efficiency of light emitted from the second emission area RE2, GE2, and BE2 of each sub pixel RSP, GSP, and BSP can be improved. In the meantime, the number of second emission areas RE2, GE2, and BE2 can vary in every second optical area RNE1, RNE2, GNE, BNE. For example, the number of second emission areas GE2 defined in the second optical area GNE of the second sub pixel GSP and the number of second emission areas BE2 defined in the second optical area BNE of the third sub pixel BSP can be larger than the number of second emission areas RE2 defined in each second optical area RNE1 and RNE2 of each first sub pixel RSP. In this case, the efficiency deviation of the second light emitting diodes ED2 located on each second optical area RNE1, RNE2, GNE, and BNE can be compensated by the number of second emission areas RE2, GE2, and BE2 defined in the second optical area RNE1, RNE2, GNE, and BNE of each sub pixel RSP, GSP, and BSP.

The optical member protection film 170 can be located on the first optical member 161 and the second optical member 162 of each sub pixels RSP, GSP, and BSP. The optical member protection film 170 can include an insulating material. For example, the optical member protection film 170 can include an organic insulating material. A refractive index of the optical member protection film 170 can be smaller than a refractive index of the first optical member 161 and a refractive index of the second optical member 162 located in each sub pixel RSP, GSP, and BSP. Accordingly, in the display device 100 according to the example embodiment of the present disclosure, light which passes through the first optical member 161 and the second optical member 162 in each sub pixel RSP, GSP, and BSP may not be reflected toward the substrate 110 due to the refractive index difference from the optical member protection film 170.

In the meantime, in a normal case, light generated from the light emitting diode of the display device is refracted by the optical member disposed in a position corresponding to the light emitting diode to be recognized by a user. However, light generated from the light emitting diode is emitted not only to a specific direction, but is emitted to all directions, so that light emitted from the light emitting diode can travel to a peripheral area of the optical member beyond the corresponding optical member. As described above, if the light generated from the light emitting diode travels to the peripheral area of the optical member, light leakage can occur in an unintended peripheral viewing angle, which can degrade the visibility of the image.

Therefore, in order to suppress the light leakage, a barrier layer can be formed in a peripheral area of the optical member. However, the barrier layer has a nature of reflecting light so that if the light generated from the light emitting diode is reflected by the barrier layer, the light can be reflected toward the substrate again. As described above, the light reflected toward the substrate can be reflected toward the top of the substrate again by the lower electrode of the light emitting diode or a metal layer which can be disposed between the light emitting diode and the barrier layer. However, the light which is consistently reflected can travel along a changed path toward another optical member located therearound, rather than the initially intended optical member corresponding to the light emitting diode.

As described above, in order to suppress the light which is reflected toward the substrate from the barrier layer from traveling toward another optical member therearound, a black matrix which absorbs light can be disposed between the light emitting diode and the barrier layer. However, in order to dispose the black matrix as described above, a separate mask needs to be additionally used, which can deteriorate the efficiency of the manufacturing process.

Accordingly, in the display device 100 according to the example embodiment of the present disclosure, the trench structure TR is formed in the vicinity of the plurality of optical members 161 and 162 and a barrier layer 195 is disposed along the trench structure TR. Accordingly, a side wall extending to the substrate 110 can be formed in the second interlayer insulating layer 117 in the vicinity of each optical member 161, 162. Accordingly, even though the light generated from the light emitting diodes ED1 and ED2 deviates from a normal traveling path, the trench structure TR formed in the second interlayer insulating layer 117 and the barrier layer 195 disposed therein can block the light from traveling to another peripheral optical members 161 and 162.

Accordingly, the display device 100 according to the example embodiment of the present disclosure blocks an abnormal traveling path of light generated from the light emitting diodes ED1 and ED2 to improve a high-angle light leakage at an unintended viewing angle. As described above, the display device 100 according to the example embodiment of the present disclosure can suppress the degradation of the cut-off performance at an unintended viewing angle. Therefore, the display device 100 according to the example embodiment of the present disclosure improves a high-angle light leakage to provide a higher quality image. As described above, the display device 100 according to the example embodiment of the present disclosure blocks light leakage at an unintended viewing angle to improve the luminous efficiency of the display device 100. Therefore, the high quality image can be provided at a lower power. Further, the display device 100 according to the example embodiment of the present disclosure includes a trench structure TR disposed so as to enclose the plurality of optical members 161 and 162 so that light which travels in an abnormal path can be reflected by the trench structure TR again. As described above, light which is reflected by the trench structure TR to be directed to the substrate 110 can be reflected toward the top of the substrate 110 again by the first lower electrode 141 or the second lower electrode 151. Further, the light which is reflected toward the top of the substrate 110 can be discharged through the first optical member 161 or the second optical member 162 along a normal path of the light. As described above, the display device 100 according to the example embodiment of the present disclosure changes a path of light which travels along the abnormal path to a normal path to improve the emission efficiency of the light emitting diodes ED1 and ED2.

Further, the display device 100 according to the example embodiment of the present disclosure includes the trench structure TR in the second interlayer insulating layer 117 so that the high-angle light leakage can be prevented or minimized without disposing a separate black matrix. Accordingly, the process for placing a separate black matrix is omitted so that the manufacturing process can be simplified. Further, a separate mask used to place the black matrix is not used so that a material cost for the manufacturing process can be saved. Accordingly, the efficiency of the manufacturing process can be improved in the display device 100 according to another example embodiment of the present disclosure.

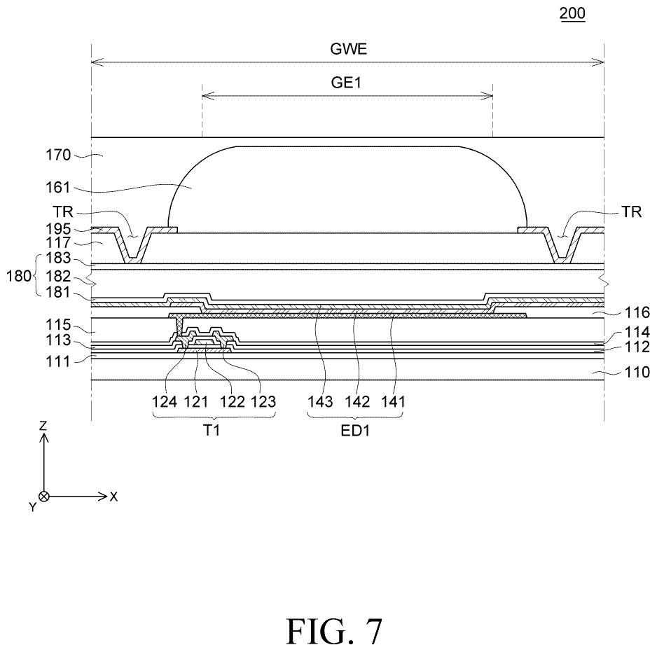

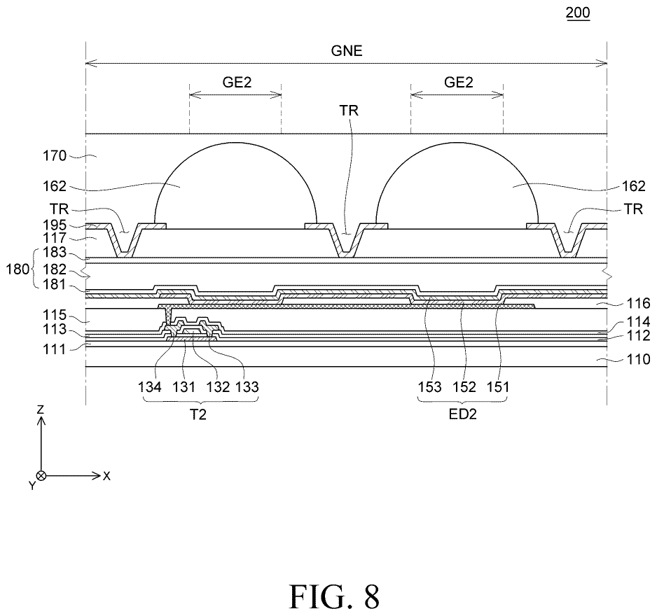

FIG. 7 is a cross-sectional view illustrating an example of a cross-sectional structure of a first optical member included in a display device according to another example embodiment of the present disclosure. FIG. 8 is a cross-sectional view illustrating an example of a cross-sectional structure of a second optical member included in a display device according to another example embodiment of the present disclosure. Incidentally, although FIGS. 7-8 show the plurality of optical members 161 and 162 covering ends (or edges, especially in a plan view) of the barrier layer 195, as an alternative embodiment, each optical member can also abut the end (or edge) of the barrier, rather than covering or overlaping the end (or edge) of the barrier layer.

Only or one difference between a display device 200 of FIGS. 7 and 8 and the display device 100 of FIGS. 1 to 6 is a shape of a trench structure TR, but the other configurations are substantially the same, so that a redundant description will be omitted or may be briefly provided.

Referring to FIGS. 7 and 8 together, the second interlayer insulating layer 117 includes a trench structure TR on a top surface. At this time, the trench structure TR can have a hole shape in which the overall second interlayer insulating layer 117 is dented. Therefore, at least a part of the second interlayer insulating layer can be spaced apart from the other part by the trench structure TR. Further, a part of the top surface of the encapsulation member 180 can be exposed by the trench structure TR. The trench structure TR has a shape in which a width is reduced downwardly, but is not limited thereto.

The barrier layer 195 which is disposed along the trench structure TR can be located on the second interlayer insulating layer 117. The barrier layer 195 can be disposed so as to cover the entire trench structure TR. For example, the barrier layer 195 can be disposed so as to entirely cover the entire side surface of the second interlayer insulating layer 117 exposed by the trench structure TR. Further, the barrier layer 195 extends along the side surface of the second interlayer insulating layer 117 to be in direct contact with the top surface of the encapsulation member 180 exposed by the trench structure TR. Further, the barrier layer 195 can be disposed so as to cover the entire exposed top surface of the encapsulation member 180.

The barrier layer 195 can be disposed so as not to overlap the first emission areas RE1, GE1, and BE1 and the second emission areas RE2, GE2, and BE2. Therefore, the barrier layer 195 can include areas which are at least partially spaced apart from each other, on the second interlayer insulating layer 117. As described above, the barrier layer 195 can be disposed so as not to interfere with a normal traveling path of light generated by the first light emitting diode ED1 and the second light emitting diode ED2.

The barrier layer 195 can be disposed so as to overlap the bank 116. The barrier layer 195 can more effectively limit an abnormal path of light generated by the first light emitting diode ED1 and the second light emitting diode ED2.

As described above, the display device 200 according to another example embodiment of the present disclosure includes a trench structure TR formed in the vicinity of the plurality of optical members 161 and 162. Accordingly, even though the light generated from the light emitting diodes ED1 and ED2 deviates from a normal traveling path, the trench structure TR and the barrier layer 195 disposed therein can more effectively block the light from traveling to another peripheral optical members 161 and 162.

Further, the display device 200 according to another example embodiment of the present disclosure blocks an abnormal traveling path of light generated from the light emitting diodes ED1 and ED2 to improve a high-angle light leakage at an unintended viewing angle. As described above, the display device 200 according to another example embodiment of the present disclosure can suppress the degradation of the cut-off performance at an unintended viewing angle. As described above, the display device 200 according to another example embodiment of the present disclosure blocks light leakage at an unintended viewing angle to improve the luminous efficiency of the display device 200. Therefore, the high quality image can be provided at a lower power. Further, the display device 200 according to another example embodiment of the present disclosure includes a trench structure TR disposed to surround a plurality of optical member so as to change a path of light which travels along an abnormal path to a normal path. Therefore, an emission efficiency of the light emitting diodes ED1 and ED2 can be more improved.

Further, in the display device 200 according to another example embodiment of the present disclosure, the trench structure 200 is disposed in a hole shape which passes through the entire thickness of the second interlayer insulating layer 117. Therefore, light which is emitted from the light emitting diodes ED1 and ED2 to travel along an abnormal path can be more effectively blocked. Accordingly, light leakage at an unintended viewing angle can be more effectively minimized or prevented.

The display device 200 according to another example embodiment of the present disclosure includes the trench structure TR in the second interlayer insulating layer 117 so that the high-angle light leakage can be minimized or prevented without disposing a separate black matrix. Accordingly, the process for placing a separate black matrix is omitted so that the manufacturing process can be more simplified. Furthermore, a separate mask used to place the black matrix is not used so that a material cost for the manufacturing process can be more saved. Therefore, the efficiency of the manufacturing process can be improved.

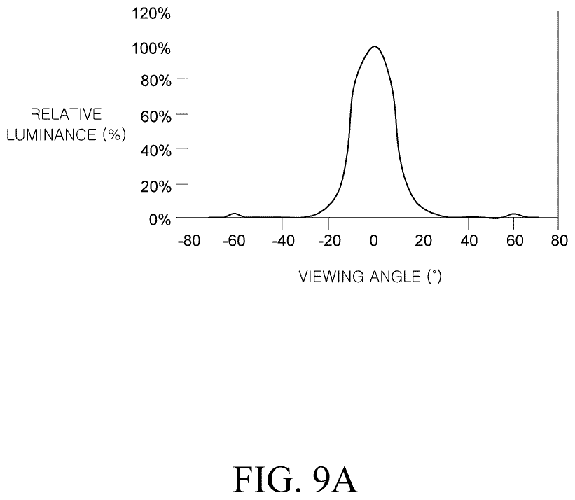

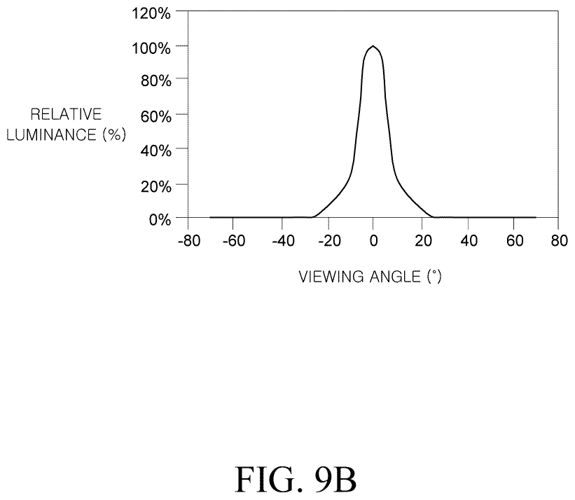

FIG. 9A is a graph illustrating a relative luminance according to a viewing angle of a display device according to Comparative Example of the present disclosure. FIG. 9B is a graph illustrating a relative luminance according to a viewing angle of a display device according to another example embodiment of the present disclosure.

In the present disclosure, the display device according to Comparative Example has the same configurations as the configurations of the display device 100 of FIGS. 1 to 6, but does not have a trench structure formed on the second interlayer insulating layer. For example, in the display device according to Comparative Example of the present disclosure, the trench structure is not formed on a top surface of the second interlayer insulating layer so that the top surface is flat.

First, referring to FIG. 9A, light emitted from the light emitting diode is refracted to a front surface direction through a corresponding optical member so that the luminance is the highest in the front surface direction, for example, in the vicinity of an area with a viewing angle of 0°. In contrast, the barrier layer is disposed in the vicinity of the optical member so that the light is blocked by the barrier layer at peripheral viewing angles so that the light is not emitted to the outside. Accordingly, in a normal case, as the viewing angle is increased based on the front surface direction, the luminance needs to decrease and converge to 0. In contrast, in the display device of Comparative Example of the present disclosure, a predetermined luminance was measured at a high angle in an area with a viewing angle of approximately ±60°. It means that the light emitted from the light emitting diode is not discharged through the corresponding optical member, but is discharged through a peripheral optical member through an abnormal path.

In contrast, referring to FIG. 9B, in the display device 200 according to another example embodiment of the present disclosure, a luminance converged to 0 at a peripheral viewing angle except for an area adjacent to the front surface direction with a viewing angle of 0°. Specifically, it was confirmed that in Comparative Example of FIG. 9A, a predetermined luminance was measured in the area with a viewing angle of approximately ±60°. However, in the display device 200 according to another example embodiment of the present disclosure, the luminance was not measured in a high angle area with a viewing angle of approximately ±60°. By doing this, it is confirmed that in the display device 200 according to another example embodiment of the present disclosure, an abnormal path through which the light emitted from the light emitting diode was discharged through the peripheral optical member was blocked by the trench structure TR.

The example embodiments of the present disclosure can also be described as follows:

According to an aspect of the present disclosure, there is provided a display device. The display device comprises a substrate, a plurality of light emitting diodes disposed on the substrate, an encapsulation member disposed on the plurality of light emitting diodes, an interlayer insulating layer which is disposed on the encapsulation member and includes a trench structure on a top surface, a barrier layer which is disposed along the trench structure on the interlayer insulating layer, and a plurality of optical members which cover ends of the barrier layer and are disposed so as to overlap the plurality of light emitting diodes.

The trench structure can have a groove shape which is concave from the top surface of the interlayer insulating layer.

The trench structure can have a hole shape which is concave from the top surface of the interlayer insulating layer to expose the encapsulation member.

A part of the encapsulation member can be exposed by the trench structure and the barrier layer can be in contact with each other.

The trench structure can be disposed so as to enclose each of the plurality of optical members.

The display device can further comprise a bank which defines emission areas of the plurality of light emitting diodes, wherein the trench structure can overlap the bank.

The display device can further comprise a touch electrode disposed on the interlayer insulating layer, wherein the barrier layer can be disposed on the same layer as the touch electrode.

The touch electrode and the barrier layer can include a reflective material.

The plurality of optical members can includes a first optical member having a shape extending in a first direction in a plan view, and a second optical member having a shape different from that of the first optical member in a plan view.

According to another aspect of the present disclosure, there is provided a display device. The display device comprise a substrate, a bank disposed on the substrate, a first light emitting diode which is disposed on the substrate and includes a first emission area defined by the bank, a second light emitting diode which is disposed on the substrate, includes a second emission area defined by the bank, and emits the same color light as the first light emitting diode, an interlayer insulating layer which covers the first light emitting diode and the second light emitting diode and includes a groove or a hole on a top surface overlapping the bank, a barrier layer which is disposed along the groove or hole on the interlayer insulating layer, a first optical member which covers ends of the barrier layer and overlaps the first emission area, and a second optical member which covers ends of the barrier layer and overlaps the second emission area.

The groove or hole can be disposed so as to enclose an outer periphery of each of the first optical member and the second optical member in a plan view.

The interlayer insulating layer can include the hole and a part of a top surface of a lower layer below the interlayer insulating layer can be exposed by the hole and the barrier layer can be in contact with the exposed part of the top surface of the lower layer.

The barrier layer can fully cover a side surface of the interlayer insulating layer which is exposed by the groove or hole.

The display device can further comprise a touch electrode disposed on the interlayer insulating layer, wherein the barrier layer is disposed on the same layer as the touch electrode and the barrier layer and the touch electrode include the same material.

The barrier layer and the touch electrode can include a reflective material.

In a plan view, the second optical member can have a shape different from that of the first optical member and can have an extension smaller than that of the first optical member at least in a first direction.

The first emission area can have a shape corresponding to that of the first optical member, and the second emission area can have a shape corresponding to that of the second optical member.

According to yet another aspect of the present disclosure, there is provided a display device. The display device comprise a substrate; a plurality of light emitting diodes disposed on the substrate; an encapsulation member disposed on the plurality of light emitting diodes; an interlayer insulating layer which is disposed on the encapsulation member and includes a trench structure on a top surface; a barrier layer which is disposed along the trench structure on the interlayer insulating layer; and a plurality of optical members which are disposed on the interlayer insulating layer, overlap the plurality of light emitting diodes, and respectively abut ends of the barrier layer.

According to still another aspect of the present disclosure, there is provided a display device. The display device comprise a substrate; a bank disposed on the substrate; a first light emitting diode which is disposed on the substrate and includes a first emission area defined by the bank; a second light emitting diode which is disposed on the substrate, includes a second emission area defined by the bank, and emits the same color light as the first light emitting diode; an interlayer insulating layer which covers the first light emitting diode and the second light emitting diode and includes a groove or a hole on a top surface overlapping the bank; a barrier layer which is disposed along the groove or hole on the interlayer insulating layer; a first optical member which is disposed on the interlayer insulating layer, overlaps the first emission area, and abuts an edge of the barrier layer; a second optical member which is disposed on the interlayer insulating layer, overlaps the second emission area, and abuts an edge of the barrier layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and All the technical concepts in the equivalent scope of the present disclosure thereof should be construed as falling within the scope of the present disclosure.

What is claimed is:

1. A display device, comprising:
a plurality of light emitting diodes disposed on a substrate;
an encapsulation member disposed on the plurality of light emitting diodes;
an interlayer insulating layer which is disposed on the encapsulation member and includes a trench structure on a top surface of the interlayer insulating layer;
a barrier layer which is disposed along the trench structure on the interlayer insulating layer; and
a plurality of optical members which cover ends of the barrier layer and are disposed so as to overlap the plurality of light emitting diodes.

2. The display device according to claim 1, wherein the trench structure has a groove shape which is concave from the top surface of the interlayer insulating layer.

3. The display device according to claim 1, wherein the trench structure has a hole shape which is concave from the top surface of the interlayer insulating layer to expose the encapsulation member.

4. The display device according to claim 3, wherein a part of the encapsulation member exposed by the trench structure and a part of the barrier layer are in contact with each other.

5. The display device according to claim 1, wherein the trench structure is disposed so as to enclose each of the plurality of optical members.

6. The display device according to claim 1, further comprising:
a bank which defines emission areas of the plurality of light emitting diodes,
wherein the trench structure overlaps the bank.

7. The display device according to claim 1, further comprising:
a touch electrode disposed on the interlayer insulating layer,
wherein the barrier layer is disposed on a same layer as the touch electrode.

8. The display device according to claim 7, wherein the touch electrode and the barrier layer include a reflective material.

9. The display device according to claim 1, wherein the plurality of optical members include:
a first optical member having a shape extending in a first direction in a plan view; and
a second optical member having a shape different from the shape of the first optical member in a plan view.

10. A display device, comprising:
a bank disposed on a substrate;
a first light emitting diode which is disposed on the substrate and includes a first emission area defined by the bank;
a second light emitting diode which is disposed on the substrate, includes a second emission area defined by the bank, and is configured to emit a same color light as the first light emitting diode;
an interlayer insulating layer which covers the first light emitting diode and the second light emitting diode and includes a groove or a hole on a top surface of that the interlayer insulating layer that overlaps the bank;
a barrier layer which is disposed along the groove or hole on the interlayer insulating layer;
a first optical member which covers ends of the barrier layer and overlaps the first emission area; and
a second optical member which covers ends of the barrier layer and overlaps the second emission area.

11. The display device according to claim 10, wherein the groove or hole of the interlayer insulating layer is disposed so as to enclose an outer periphery of each of the first optical member and the second optical member in a plan view.

12. The display device according to claim 10, further comprising a lower layer disposed below the interlayer insulating layer,
wherein the interlayer insulating layer includes the hole,
wherein a part of a top surface of the lower layer below the interlayer insulating layer is exposed by the hole, and
wherein the barrier layer is in contact with the exposed part of the top surface of the lower layer.

13. The display device according to claim 10, wherein the barrier layer fully covers a side surface of the interlayer insulating layer which is exposed by the groove or hole.

14. The display device according to claim 10, further comprising:
a touch electrode disposed on the interlayer insulating layer,
wherein the barrier layer is disposed on a same layer as the touch electrode, and the barrier layer and the touch electrode include a same material.

15. The display device according to claim 14, wherein the barrier layer and the touch electrode include a reflective material.

16. The display device according to claim 10, wherein in a plan view, the second optical member has a shape different from a shape of the first optical member and has an extension smaller than an extension of the first optical member at least in a first direction.

17. The display device according to claim 10, wherein the first emission area has a shape corresponding to a shape of the first optical member, and the second emission area has a shape corresponding to a shape of the second optical member.

18. A display device, comprising:
a substrate;
a plurality of light emitting diodes disposed on the substrate;
an encapsulation member disposed on the plurality of light emitting diodes;
an interlayer insulating layer which is disposed on the encapsulation member and includes a trench structure on a top surface of the interlayer insulating layer;
a barrier layer which is disposed along the trench structure on the interlayer insulating layer; and
a plurality of optical members which are disposed on the interlayer insulating layer and overlap the plurality of light emitting diodes, and respectively abut ends of the barrier layer.

19. A display device, comprising:
a substrate;
a bank disposed on the substrate;
a first light emitting diode which is disposed on the substrate and includes a first emission area defined by the bank;
a second light emitting diode which is disposed on the substrate, includes a second emission area defined by the bank, and is configured to emit a same color light as the first light emitting diode;
an interlayer insulating layer which covers the first light emitting diode and the second light emitting diode, and includes a groove or a hole on a top surface overlapping the bank;
a barrier layer which is disposed along the groove or hole on the interlayer insulating layer;
a first optical member which is disposed on the interlayer insulating layer, overlaps the first emission area, and abuts an edge of the barrier layer; and
a second optical member which is disposed on the interlayer insulating layer, overlaps the second emission area, and abuts an edge of the barrier layer.

20. The display device according to claim 19, further comprising a touch electrode disposed on the interlayer insulating layer,
wherein the touch electrode and the barrier layer include a reflective material.
